(19) United States
(12) Patent Application Publication
(10) Pub. No.: US 2024/0145515 A1
(43) Pub. Date: May 2, 2024

(54) STACKED INTEGRATED CIRCUIT DIES AND INTERCONNECT STRUCTURES

(71) Applicant: SEMICONDUCTOR COMPONENTS INDUSTRIES, LLC, Scottsdale, AZ (US)

(72) Inventors: Swarnal BORTHAKUR, Boise, ID (US); Mario M. PELELLA, Mountain View, CA (US); Chandrasekharan KOTHANDARAMAN, New York, NY (US); Marc Allen SULFRIDGE, Boise, ID (US); Yusheng LIN, Phoenix, AZ (US); Larry Duane KINSMAN, Redding, CA (US)

(73) Assignee: SEMICONDUCTOR COMPONENTS INDUSTRIES, LLC, Scottsdale, AZ (US)

(21) Appl. No.: 18/558,593

(22) PCT Filed: Apr. 27, 2022
(86) PCT No.: PCT/US2022/071946

§ 371 Date: Nov. 2, 2023

Related U.S. Application Data
(60) Provisional application No. 63/211,988, filed on Jun. 17, 2021.

(51) Int. Cl. H01L 27/146; H01L 23/00

(52) U.S. Cl. CPC H01L 27/14634; H01L 24/05; H01L 24/06; H01L 24/08; H01L 24/19; H01L 24/20; H01L 24/94; H01L 24/96; H01L 27/14636; H01L 24/13; H01L 24/32; H01L 24/80; H01L 2224/05647; H01L 2224/06181; H01L 2224/08145; H01L 2224/08225; H01L 2224/13025; H01L 2224/19; H01L 2224/211; H01L 2224/32225; H01L 2224/80357; H01L 2224/80379; H01L 2224/80896; H01L 2224/94; H01L 2224/96; H01L 2924/05442

(57) ABSTRACT

An integrated circuit package (34, 34′, 34″) may be implemented by stacked first, second, and third integrated circuit dies (40, 50, 60). The first and second dies (40, 50) may be bonded to each other using corresponding inter-die connection structures (74-1, 84-1) at respective interfacial surfaces facing the other die. The second die (50) may also include a metal layer (84-2) for connecting to the third die (60) at its interfacial surface with the first die (40). The metal layer (84-2) may be connected to a corresponding inter-die connection structure (64) on the side of the third die (60) facing the second die (50) through a conductive through-substrate via (84-2) and an additional metal layer (102) in a redistribution layer (96) between the second and third dies (50, 60). The third die (60) may have a different lateral outline than the second die (50).

This application claims the benefit of U.S. provisional patent application No. 63/211,988, filed on Jun. 17, 2021, which is incorporated by reference herein in its entirety.

### BACKGROUND

This relates generally to systems with stacked integrated circuit dies, and more specifically, to interconnect structures on stacked integrated circuit dies.

In particular, electronic systems such as an imaging system can include circuitry implemented using an integrated circuit package having multiple integrated circuit dies stacked on top of one another. It may be desirable to include stacked integrated circuit dies of different technology nodes and/or die sizes to enhance and optimize the performance of each die, and therefore, of the overall package.

However, it may be difficult to efficiently implement a compact integrated circuit package having stacked integrated circuit dies of different die sizes. As an example, implementing stacked integrated circuit dies using wafer-to-wafer manufacturing processes can require matching die sizes between the dies, which can restrict types of dies used and therefore limit system performance.

It is within this context that the embodiments herein arise.

### BRIEF DESCRIPTION OF THE DRAWINGS

FIG. 1 is a functional block diagram of an illustrative system having a stacked-die package in accordance with some embodiments.

FIG. 2 is a functional block diagram of illustrative image sensor circuitry having an image sensor pixel array and control and readout circuitry for the pixel array in accordance with some embodiments.

FIG. 3 is a diagram of an illustrative image sensor implemented using stacked integrated circuit dies in accordance with some embodiments.

FIGS. 4A-4F are diagrams of illustrative processes for forming an image sensor such as the image sensor shown in FIG. 3 in accordance with some embodiments.

FIGS. 5A-5F are diagrams of illustrative processes for forming a through-substrate via on a stacked-wafer structure in accordance with some embodiments.

FIGS. 6A-6F are diagrams of illustrative processes for forming a stacked-die package with wire-bond connections in accordance with some embodiments.

FIGS. 7A and 7B are diagrams of illustrative processes in forming a stacked-die package having a larger base die with wire-bond connections in accordance with some embodiments.

FIGS. 8A-8C are diagrams of illustrative outlines of stacked dies in a stacked-die package in accordance with some embodiments.

### DETAILED DESCRIPTION

Electronic systems often include integrated circuits implemented on dies (sometimes referred to as chips). In particular, specialized integrated circuit dies may be mounted to (e.g., stacked on top of) one another to form a stacked-die package in order to optimize performance. Generally, electronic systems of any type may utilize these stacked-die packages. Arrangements in which an imaging system (e.g., an electronic system utilizing one or more image sensors) is implemented using on a stacked-die package are described herein as illustrative examples. If desired, any system may similarly implement and utilize the types of stacked-die packages described herein.

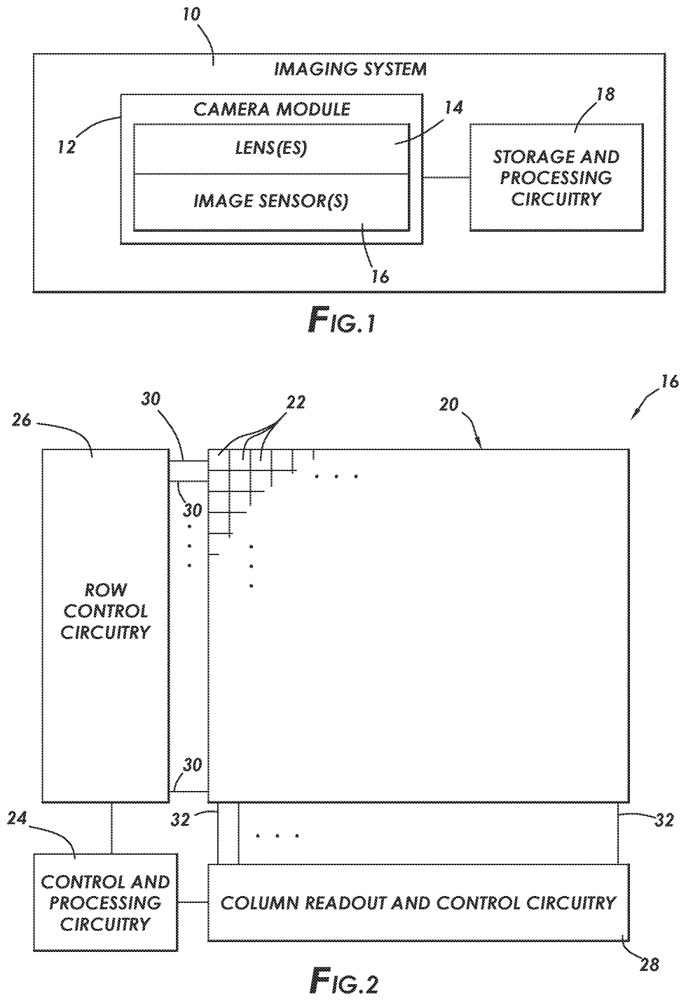

FIG. 1 is a functional block diagram of an illustrative imaging system such as an electronic device that uses an image sensor to capture images. Imaging system 10 of FIG. 1 may be a portable electronic device such as a camera, a cellular telephone, a tablet computer, a webcam, a video camera, a video surveillance system, an automotive imaging system, a video gaming system with imaging capabilities, an augmented reality and/or virtual reality system, an unmanned aerial vehicle system (e.g., a drone), an industrial system, or any other desired imaging system or device that captures image data. Camera module 12 (sometimes referred to as an imaging module) may be used to convert incoming light into digital image data. Camera module 12 may include one or more (macro) lenses 14 and one or more image sensors 16. During image capture operations, light from a scene may be focused onto each image sensor 16 by one or more (macro) lenses 14. Image sensor 16 may include circuitry for converting analog pixel image signals into corresponding digital image data that is provided to storage and processing circuitry 18.

Storage and processing circuitry 18 may include one or more integrated circuits (e.g., image processing circuits, microprocessors, storage devices such as random-access memory and non-volatile memory, etc.) and may be implemented using components that are separate from the camera module and/or components that form part of the camera module (e.g., circuits that form part of an integrated circuit that includes an image sensor 16 or an integrated circuit within the module that is associated with an image sensor 16). When storage and processing circuitry 18 is included on different integrated circuits than those of image sensors 16, the integrated circuits with circuitry 18 may be vertically stacked or packaged with respect to the integrated circuits with image sensors 16. Image data that has been captured by camera module 12 may be processed and stored using processing circuitry 18 (e.g., using an image processing engine on processing circuitry 18, using an imaging mode selection engine on processing circuitry 18, etc.). Processed image data may, if desired, be provided to external equipment (e.g., a computer, an external display, or other devices) using wired and/or wireless communication paths coupled to processing circuitry 18.

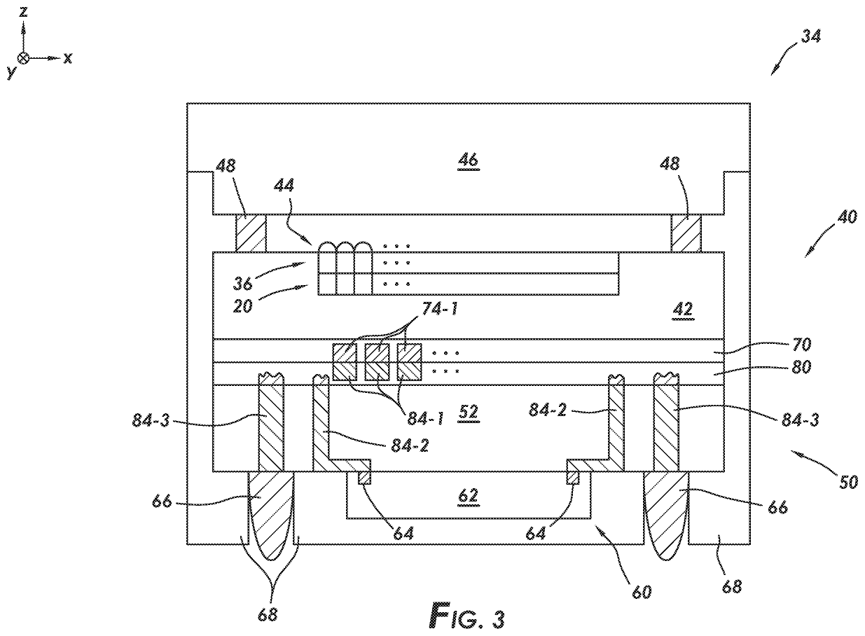

As shown in FIG. 2, an image sensor 16 may include a pixel array such as pixel array 20 containing image sensor pixels 22 arranged in rows and columns (sometimes referred to herein generically as lines) and control and processing circuitry 24 (sometimes referred to herein simply as control circuitry 24). Pixel array 20 may contain, for example, hundreds or thousands of rows and columns of image sensor pixels 22. Control circuitry 24 may be coupled to row control circuitry 26 (e.g., row driver circuitry or row drivers) and column readout and control circuitry 28 (sometimes referred to as column control circuitry, column readout circuitry, image readout circuitry, readout circuitry, or column decoder circuitry).

Row control circuitry 26 may receive row addresses from control circuitry 24 and supply corresponding row control signals such as reset, anti-blooming, row-select, charge transfer, dual conversion gain, and readout control signals to pixels 22 over conductive lines or paths 30 (e.g., pixel row control paths, or simply, control paths). In particular, each pixel row may receive different control signals over a corresponding number of control paths such that each pixel row is coupled to multiple conductive paths 30. One or more conductive lines or paths 32 (e.g., pixel column readout paths, or simply, readout paths) may be coupled to each column of pixels 22. Conductive paths 32 may be used for reading out image signals from pixels 22 and for supplying bias signals (e.g., bias currents or bias voltages) to pixels 22. As an example, during a pixel readout operation, a pixel row in pixel array 20 may be selected using row control circuitry 26 and image signals generated by the selected image pixels 22 in that pixel row can be read out along conductive paths 32.

Column readout circuitry 28 may receive image signals (e.g., analog pixel values generated by pixels 22) over conductive paths 32. Column readout circuitry 28 may include memory or buffer circuitry for temporarily storing calibration signals (e.g., reset level signals, reference level signals) and/or image signals (e.g., image level signals) read out from array 20, amplifier circuitry or a multiplier circuit, analog to digital conversion (ADC) circuitry, bias circuitry, latch circuitry for selectively enabling or disabling portions of column readout circuitry 28, or other circuitry that is coupled to one or more columns of pixels in array 20 for operating pixels 22 and/or for reading out image signals from pixels 22. ADC circuitry in readout circuitry 28 may convert analog pixel values received from array 20 into corresponding digital pixel values (sometimes referred to as digital image data or digital pixel data). Column readout circuitry 28 may supply digital pixel data from pixels 22 in one or more pixel columns to control and processing circuitry 24 and/or processor 18 (FIG. 1) for further processing and/or storage.

Pixel array 20 may be provided with a filter array having multiple (color) filter elements (each corresponding to a respective pixel) which allows a single image sensor to sample light of different colors or sets of wavelengths.

Image sensor pixels 22 may be formed in a semiconductor substrate using complementary metal-oxide-semiconductor (CMOS) technology or charge-coupled device (CCD) technology or any other suitable photosensitive device technology. Image sensor pixels 22 may be frontside illumination (FSI) image sensor pixels or backside illumination (BSI) image sensor pixels. Arrangements in which image sensor 16 is implemented as a BSI image sensor are described herein as illustrative examples.

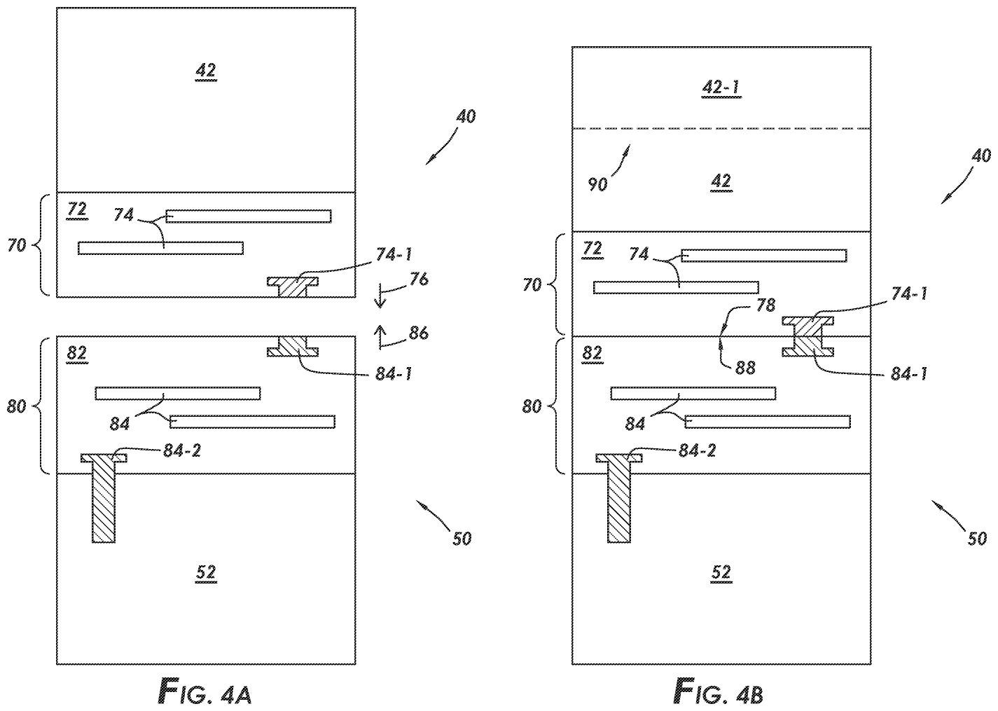

Image sensor 16 may be implemented using an integrated circuit package or other structure in which multiple integrated circuit dies are mounted to (e.g., vertically stacked on top of) one another. FIG. 3 is a diagram of an illustrative image sensor (e.g., image sensor 16 in FIGS. 1 and 2) implemented using an integrated circuit package containing multiple integrated circuit dies mounted to each other. In the example of FIG. 3, integrated circuit package 34 may include a first integrated circuit die such as die 40 mounted to a second integrated circuit die such as die 50, which is mounted to a third integrated circuit die such as die 60.

In one illustrative arrangement described herein as an example, integrated circuit die 40 may be a pixel circuitry integrated circuit die, integrated circuit die 50 may be a sample-and-hold (memory) circuitry integrated circuit die, and integrated circuit die 60 may be a control and processing circuitry integrated circuit die (e.g., implemented as an application-specific integrated circuit (ASIC) die). This arrangement is merely illustrative. If desired, other arrangements of dies having varying functions may be used to form image sensor integrated circuit package 34.

As shown in FIG. 3, die 40 may include a substrate such as substrate 42 formed from semiconducting material such as silicon. Die 40 may be processed to form elements within image sensor pixel array 20 (e.g., image sensor pixel array 20 in FIG. 2). In particular, image sensor pixel array 20 may include pixel photosensitive elements such as photodiodes and other image sensor pixel elements such as pixel transistors, floating diffusion regions, charge storage elements, etc., formed at a backside (the top side in the perspective of FIG. 3) of substrate 42, thereby implementing BSI pixels.

Light filter elements in a light filter layer 36 (e.g., a color filter array) and microlenses in a microlens layer 44 may overlap pixel array 20 on the backside of substrate 42. Microlens layer 40 formed on the back surface may focus incident light onto pixel array 20. Varying types of light filter elements (e.g., configured to pass through light of varying wavelengths such as red light, green light, blue light, infrared light, etc.) in light filter layer 36 may configure pixels 22 in pixel array 20 to be sensitive to light of different wavelengths. A glass layer or other protective layer such as layer 46 may be disposed over the backside of substrate 42 and may be supported by support structures 48. Layer 46 may be transparent in the wavelengths of light, to which pixels 22 in pixel array 20 are sensitive. Support structures 48 may attach layer 46 to the back surface of substrate 42 using adhesive or other intervening attachment structures. If desired, support structures 48 may form a continuous seal around a portion of the substrate backside at which the light sensing elements are disposed. In other words, layer 46 may be separated from microlens layer 44 by a sealed-off gap. If desired, the gap may be filled with air or any other suitable medium.

Interconnect layer 70 may be formed on the front side (the bottom side in the perspective of FIG. 3) of substrate 42. Interconnect layer 70 may include one or more layers of conductive material, such as metal layers, selectively connected to one another using conductive vias. Interconnect layer 70 may include one or more layers of dielectric material, such as silicon dioxide (sometimes referred to as oxide) layers, that selectively separate and isolate portions of conductive layers and/or vias from one another.

As shown in FIG. 3, die 50 may include a substrate such as substrate 52 formed from semiconducting material such as silicon. Interconnect layer 80 may be formed on a first side (the top side in the perspective of FIG. 3) of substrate 52. Interconnect layer 80 may include one or more layers of conductive material, such as metal layers, selectively connected to one another using conductive vias. Interconnect layer 80 may include one or more layers of dielectric material, such as silicon dioxide layers, that selectively separate and isolate portions of conductive layers and/or vias from one another.

Integrated circuit die 50 may implement memory circuitry for the pixel circuitry on integrated circuit die 40. As an example, die 50 may include per-pixel data storage elements such as capacitors or other analog charge storage structures, or digital data storage structures. In other words, for each pixel 22 in pixel array 20 implemented on die 40, integrated circuit die 50 may include one or more capacitors and/or other data storage structures coupled to that pixel 22. In addition to the one or more data storage structures in each per-pixel data storage circuitry, each per-pixel data storage circuitry may also include transistors and/or other active or passive electrical elements. As an example, each pixel 22 on die 40 may be coupled to a set of three, four, eight, etc., data storage elements via corresponding intervening switching transistors on die 50. The data storage circuitry (and/or other portions of sample-and hold circuitry) may be formed on substrate 52 and/or interconnect layer 80.

In order to facilitate electrical connections between each pixel 22 in pixel array 20 on die 40 and the corresponding per-pixel data storage circuitry on die 50, dies 40 and 50 may be connected to each other using an array of per-pixel inter-die electrical connections. In the example of FIG. 3, interconnect layer 70 may include one or more metal layers, vias, and/or bond pad structures that form inter-die connection structures 74-1 at the bonding interface (surface) with die 50. Interconnect layer 80 may include one or more metal layers, vias, and/or bond pad structures that form corresponding (matching) inter-die connection structures 84-1 at the bonding interface (surface) with die 40. In some illustrative arrangements described herein as examples, the bonding surface of interconnect layer 70 (the bottom surface in the perspective of FIG. 3) and the bonding surface of interconnect layer 80 may be fused or bonded using a hybrid bond process. In other words, inter-die connection structures 74-1 and 84-1 may form hybrid bonds that electrically connect pixel circuitry on die 40 to sample-and-hold (data storage) circuitry on die 50.

If desired, each inter-die connection formed by a matching pair of structures 74-1 and 84-1 may be configured to connect pixel circuitry for a single pixel on die 40 to data storage circuitry (e.g., one or more capacitors) for that pixel on die 50. Because circuitry on die 50 are provided on a per-pixel basis, each per-pixel data storage circuit (e.g., each set of capacitors for a given pixel) may sometimes be considered to form a portion of a corresponding pixel in the image sensor. In other words, die 50 may include an array of data storage circuits corresponding to the array of pixel circuitry on die 40. If desired, each inter-die connection may be shared by multiple pixels or each pixel may have multiple inter-die connections.

As shown in FIG. 3, die 60 may include a substrate such as substrate 62 formed from semiconducting material such as silicon. Die 60 may implement pixel control circuitry (e.g., circuitry for operating the pixel elements such as driver circuitry configured to provide control signals to pixel transistors such as circuitry 26 in FIG. 2), pixel readout circuitry (e.g., circuitry for receiving and processing image signals and other pixel-generated signals from the pixel elements such as circuitry 28 in FIG. 2), timing control circuitry (e.g., circuitry for coordinating pixel control and readout operations such as circuitry 24 in FIG. 2), (digital) image signal processing circuitry and (digital) memory circuitry (such as circuitry 18 in FIG. 1 and/or circuitry 24 in FIG. 2), and/or other support or peripheral circuitry for supporting the operation of the image sensor (e.g., clock circuitry, interface circuitry, power management circuitry, etc.). If desired, one or more of these functionalities may be implemented on a different stacked die (e.g., on die 50). If desired, multiple separate integrated circuit dies each mounted to die 50 may implement some or all of these functionalities in combination.

In some illustrative scenarios, it may be desirable to form a stacked-die image sensor with integrated circuit dies formed from different technologies (e.g., formed from different technology nodes) to improve image sensor performance. As an example, die 60 may be an ASIC die formed from a higher technology node (e.g., a 40-nm process, a 28-nm process, etc.) than dies 40 and 50 (e.g., formed from a 65-nm process).

In this example, as illustrated in FIG. 3, die 60 may be smaller in size (e.g., smaller along one or both lateral dimensions such as a length along the x-axis and a width along the y-axis) than dies 40 and 50. If desired, die 60 may be larger in size (e.g., larger along one or both lateral dimensions such as a length along the x-axis and a width along the y-axis) than dies 40 and 50. In this configuration, die 60 may be mounted to die 50 at the bottom surface (in the perspective of FIG. 3) of die 50. In particular, inter-die connection structures 84-2 on die 50 and matching inter-die connection structures 64 on die 60 may be connected to each other to form the inter-die connections between dies 50 and 60.

While inter-die connections between dies 40 and 50 are formed on a per-pixel basis, inter-die connections between dies 50 and 60 may be formed on a per-pixel-column and/or per-pixel-row basis (e.g., per line of pixels). In other words, each inter-die connection between dies 50 and 60 formed from connecting a pair of inter-die connection structures 84-2 and 64 may be coupled to a line of pixels in array 20 on die (e.g., through intervening sample-and-hold circuitry on die 50).

As a first example, pixel (column) readout circuitry implemented on die 60 may be coupled to pixel circuitry on die 40 through intervening sample-and-hold circuitry on die 50 using conductive (column) lines 32 in FIG. 2 to form readout paths. Some of the inter-die connections between dies 50 and 60 may be used to form portions of conductive lines 32 coupling the pixel readout circuitry to corresponding columns of sample-and-hold circuitry portions on die 50 and to columns of pixels in pixel array 20 on die 40.

As a second example, pixel (row) control circuitry implemented on die 60 may be coupled to and control pixel circuitry on die 40 and sample-and-hold circuitry on die 50 using conductive (row) lines 30 in FIG. 2 to form control paths. Some of the inter-die connections between dies 50 and 60 may be used to form portions of conductive lines 32 coupling pixel control circuitry to corresponding rows of sample-and-hold circuitry portions on die 50 and to rows of pixels in pixel array 20 on die 40.

These examples are merely illustrative. If desired, inter-die connections between dies 60 and 50 may form connections to dies 40 and 50 in other arrangements (e.g., a connection made to a portion of a pixel column, a connection made to a portion of a pixel row, a connection made to a desired set of pixels spanning multiple columns and rows, etc.).

The inter-die connections between dies 50 and 60 may be formed using any suitable types of bonding process at the respective interfaces between dies 50 and 60. As examples, inter-die connection structures 84-2 and matching inter-die connection structures 64 may be connected based on hybrid bonds, using intervening micro-bumps such as solder bumps, or any other suitable structures for making physical and electrical connections. Because die 60 has a smaller footprint or outline (e.g., with one or more smaller lateral dimensions) than die 50, the inter-die connections between dies 50 and 60 may include fan-in structures toward die 60 (or fan-out structures toward die 50). These fan-in structures may be formed from one or more redistribution layer (e.g., one or more metal layers in a redistribution layer that implement the fan-in features). In the example of FIG. 3, a redistribution layer may be formed on the bottom surface (in the perspective of FIG. 3) of die 50 and is shown as part of inter-die connection structures 84-2.

As examples, each inter-die connection structure 84-2 may also include bond pads (e.g., formed on a redistribution layer and/or to which a metal layer in the redistribution layer is attached), may include conductive vias such as through-oxide vias and through-substrate vias (e.g., through-silicon vias) that extend from a bottom side (in the perspective of FIG. 3) of substrate 52 to a top side (in the perspective of FIG. 3) of substrate 52 at which interconnect layer 80 is formed, may include one or more metal layers in a redistribution layer and/or in interconnect layer 80. Each inter-die connection structure 64 may be formed from structures in die 60 analogous to the structures (on die 50) disclosed above to be included in each inter-die connection structure 84-2. Accordingly, depending on how die 60 is mounted to and/or is electrically connected to die 50, intervening connection elements such as micro-bumps or solder bumps, copper pads, etc., may exist between corresponding pairs of inter-die connection structures on dies 50 and 60.

A molding compound 68 such as a resin or plastic compound may be used to encapsulate integrated circuit package 34 (e.g., stacked dies 40, 50, and 60) on the bottom side (in the perspective of FIG. 3) of dies 50 and 60, on the sides of dies 40, 50, and 60, etc. As shown in FIG. 3, molding compound 68 may extend to the lateral sides glass layer 46 on the top side (in the perspective of FIG. 3) of integrated circuit package 34. This allows incident light to be conveyed to the light-sensitive elements in the image sensor through glass layer 46, while protecting stacked dies 40, 50, and 60 from contaminants.

External access to integrated circuit package 34 may be provided using solder bumps 66 on corresponding bond pads of the bottom surface (in the perspective of FIG. 3) of die 50. As an example, solder bumps 66 may connect integrated circuit package 34 to a printed circuit board or other substrate. In the example of FIG. 3, connection structures 84-3 on die 50 may provide solder bump connections (to an external circuit board) with connections to one or more metal layers on interconnect layer 80, and thereby to other circuitry on dies 40, 50, and 60. Connection structures 84-3 may be formed from one or more metal layers in interconnect layer 80 on die 50, a conductive through-substrate via, one or more additional metal layers (e.g., in a redistribution layer) on the bottom side (in the perspective of FIG. 3) of die 50.

The configurations of dies 40, 50, and 60 implementing their corresponding functions for an image sensor are merely illustrative. If desired, dies for different functions (e.g., to implement other types of sensor circuitry, to implement non-imaging functions, etc.) may similarly be used to form integrated circuit package 34.

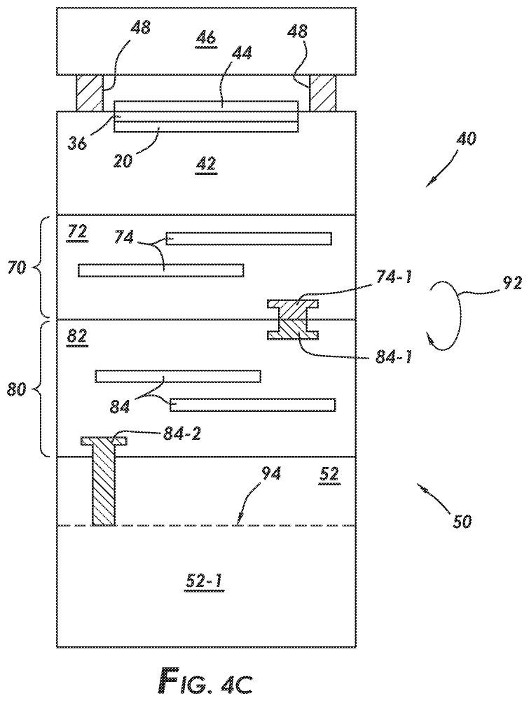

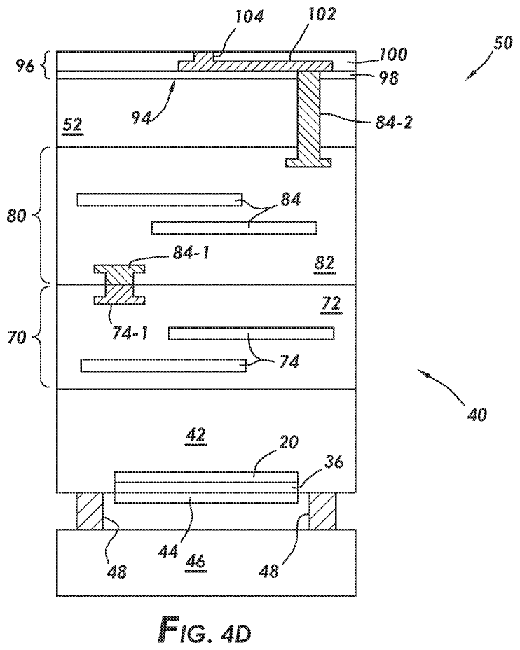

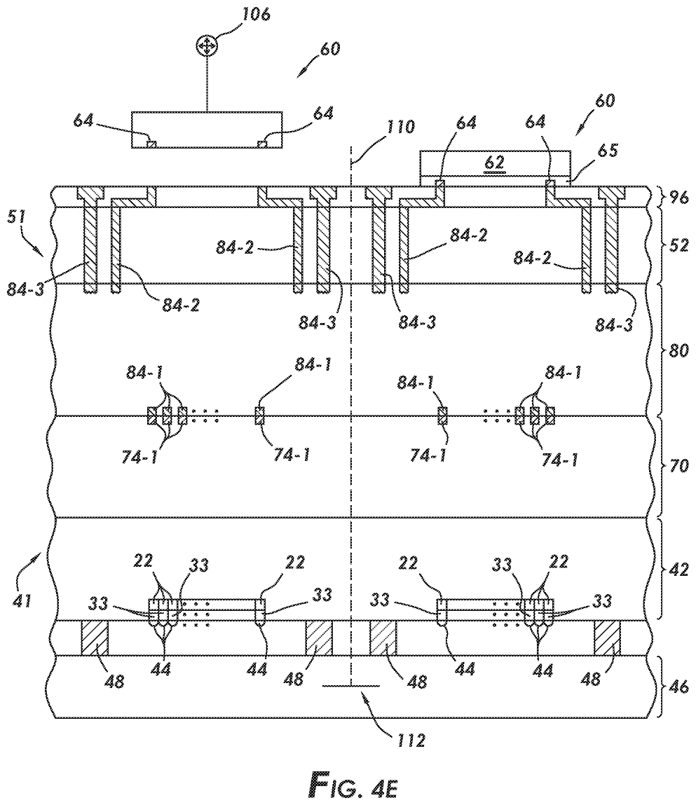

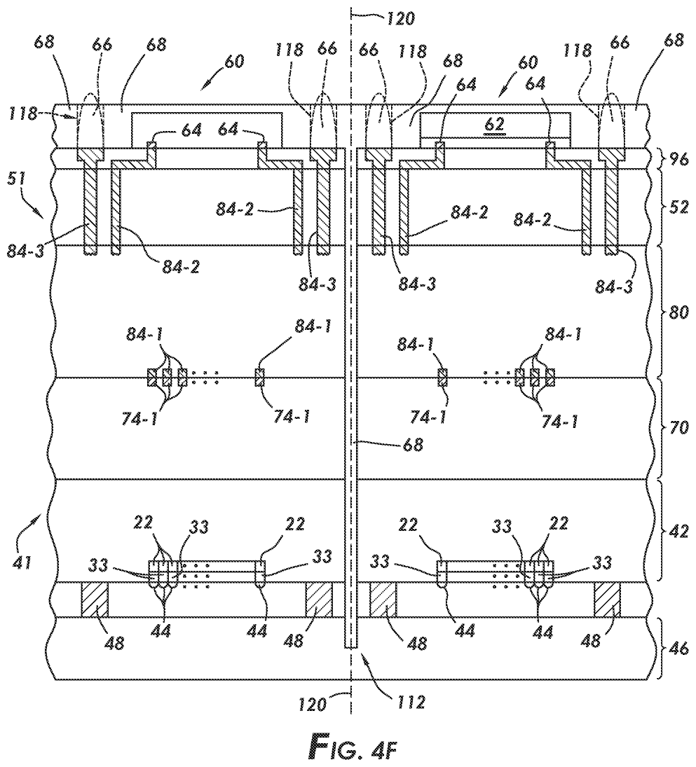

Because of the differing (lateral) dimensions between the stacked integrated circuit dies (e.g., between integrated circuit dies 50 and 60), it may be difficult to efficiently manufacture integrated circuit packages 34. Accordingly, FIGS. 4A-4F illustrate one or more processes that may be employed to implement integrated circuit packages 34.

In particular, FIGS. 4A-4D illustrate wafer-level processes at a die-level (e.g., by showing individual dies) in order not to obscure the present embodiments. As an example, while FIGS. 4A-4D show processing of first die 40, second die 50, and the stacked-die structure resulting from dies 40 and 50 being stacked on one another, these processes may, if desired, take place (simultaneously) across a first (un-singulated or un-diced) wafer of integrated circuit dies 40, a second (un-singulated or un-diced) wafer of integrated circuit dies 50, and the stacked-wafer structure resulting from the first and second wafers being stacked on one another.

As shown in FIG. 4A, each integrated circuit die 40 (e.g., one of many dies 40 on an un-singulated wafer) may have a semiconductor substrate 42. Structures for interconnect layer 70 may be formed on a first side (the bottom side in the perspective of FIG. 4A) of substrate 42. To form interconnect layer 70, layers of dielectric material and conductive material may be deposited, patterned, planarized, etc., to form conductive layers and vias such as metal layers 74 separated by one or more dielectric layers 72. An illustrative inter-die connection structure 74-1 configured to provide (electrical and/or physical) connection to another die (e.g., a corresponding die 50) may be formed at the surface interfacing die 40 with a corresponding die 50. As an example, inter-die connection structure 74-1 may include a metal layer and a bond pad on the metal layer. The bond pad may be exposed at the interfacial surface of die 40 for attachment with a corresponding die 50.

Similarly, each integrated circuit die 50 (e.g., one of many dies 50 on an un-singulated wafer) may have a semiconductor substrate 52. Structures for interconnect layer 80 may be formed on a first side (the top side in the perspective of FIG. 4A) of substrate 52. To form interconnect layer 80, layers of dielectric material and conductive material may be deposited, patterned, planarized, etc., to form conductive layers and vias such as metal layers 84 separated by one or more dielectric layers 82. An illustrative inter-die connection structure 84-1 configured to provide (electrical and/or physical) connection to another die (e.g., a corresponding die 40) may be formed at the surface interfacing die 50 with a corresponding die 40. As an example, inter-die connection structure 84-1 may include a metal layer and a bond pad on the metal layer. The bond pad may be exposed at the interfacial surface of die 50 for attachment with a corresponding die 40.

Another illustrative inter-die connection structure 84-2 configured to provide (electrical and/or physical) connection to another die (e.g., a corresponding die 60) may be formed at the interfacial surfaces between substrate 52 and interconnect layer 80. As an example, inter-die connection structure 84-2 may include a metal layer and a conductive through-substrate via (e.g., a through-silicon via) connected to the metal layer and that extends into (e.g., at least partially through) substrate 52.

While a single instance of each type of inter-die connection structure is shown in FIG. 4A, this is merely illustrative. As described in connection with FIG. 3, dies 40 and 50 may include any suitable number of pixel-level (per-pixel) inter-die connection structures 74-1 and 84-1 (e.g., a number of inter-die connection structures 74-1 and 84-1 on the order of the number of pixels in array 20). As described in connection with FIG. 3, die 50 may include any suitable number of column/row-level (per-line) inter-die connection structures 84-2 (e.g., a number of inter-die connection structures 84-2 on the order of the number of pixel columns and/or pixel rows in array 20).

Each die 40 (e.g., the un-singulated wafer containing dies 40) may move in direction 76 toward a corresponding die 50 (e.g., the corresponding un-singulated wafer containing dies 50) and/or each die 50 may move in direction 86 toward a corresponding die 40 to attach the two wafers to each other. As shown in FIG. 4B, each die 40 may be attached to a corresponding die 50 at respective interfacial surfaces 78 and 88. In particular, a wafer-to-wafer bonding process may be used to form the pixel-level hybrid bonds using inter-die connection structures 74-1 and 84-1 (e.g., copper-to-copper hybrid bonds using copper pads on respective structure 74-1 and 84-1). In particular, during the wafer-to-wafer bonding process, each matching pair of a connection structure 74-1 and a connection structure 84-1 may be aligned and fused. Dielectric material in layers 72 and 82 at interfacial surfaces 78 and 88 may also be bonded and fused to each other during the bonding process. This may result in a stacked-wafer structure (e.g., multiple stacked-die structures on the un-singulated stacked-wafer structure).

In preparation for forming the pixel circuitry on each die 40, substrate 42 may be thinned (at the wafer-level) to a desired thickness. In particular, the thinning process may remove substrate portion 42-1 and result in a new surface 92 at which an image sensor pixel layer, a light filter layer, and a microlens layer may be formed. As shown in FIG. 4C, pixel array 20, overlapping light filter layer 36, and overlapping microlens layer 44 may be formed on the top side (in the perspective of FIG. 4C) of each die 40 opposite to the bottom side (in the perspective of FIG. 4C) bonded to a corresponding die 50. Layer 46 such as a protective layer or a glass layer (sometimes referred to as a glass cover or glass member) may then be disposed over the top side of each die 40 and supported by corresponding support structures 48. As examples, one or more support structures 48 may be adhered, fused, or otherwise attached to substrate 42 and layer 46. These structures on each die 40 may be formed at the wafer-level (e.g., using simultaneous formation of the same structures on multiple dies 40 of an un-singulated stacked-wafer structure).

Processing may proceed with the bottom side (in the perspective of FIG. 4C) of each die 50. If desired, the stacked-wafer structure may be flipped as indicated by arrow 92 to facilitate processing of the bottom side of each die 50. In preparation for forming inter-die connection structures on the bottom side of each die 50, substrate 52 may be thinned (at the wafer-level) to a desired thickness. In particular, the thinning process may remove substrate portion 52-1 and result in a new surface 94. The new surface 94 may be near or at an end of inter-die connection structure 84-2 in substrate 52 (e.g., an end of a through-silicon via forming a portion of structure 84-2).

As shown in FIG. 4D, new structures for inter-die connection structure 84-2 may be formed on each die 50 to facilitate connection to a corresponding die 60. In one illustrative arrangement, inter-die connection structure 84-2 may be configured to form a hybrid bond with the corresponding inter-die connection structure 64 on die 60 (FIG. 3). In this illustrative arrangement, a redistribution layer such as redistribution layer 96 may be formed to provide an extension of inter-die connection structure 84-2 (e.g., thereby forming a fan-in structure in scenarios where the die to be attached is smaller, or forming a fan-out structure in scenarios where the die to be attached is larger).

In particular, one or more silicon nitride layers such as layer 98, one or more silicon dioxide layers such as layer 100, and one or more conductive layers such as metal layer 102 and bond pad 104 may be formed as part of redistribution layer 96. Metal layer 102 may extend between bond pad 104 and the through-silicon via portion of connection structure 84-2. Bond pad structure 104 (e.g., a copper bond pad) may be exposed at the top surface (in the perspective of FIG. 4D) of redistribution layer 96 for attachment with die 60 and may be fused with the (copper) bond pad of corresponding connection structure 64 on die 60 to form a hybrid bond. Dielectric material at the interfacial surface of redistribution layer 96 may also fuse with the dielectric material at the interfacial surface of die 60 during the hybrid bonding process.

In another illustrative arrangement, inter-die connection structure 84-2 may be configured to form a micro-bump (e.g., solder) connection with the corresponding inter-die connection structure 64 on die 60 (FIG. 3). In this illustrative arrangement, a redistribution layer similar to redistribution layer 96 of FIG. 4D may be implemented. In addition to the structures of redistribution layer 96 as shown in FIG. 4D, inter-die connection structure 84-2 may further be configured to form the micro-bump connection. In particular, a seed layer (e.g., a tin-copper seed layer) may be formed between metal layer 102 and (copper) bond pad 104, and an additional metal plating layer (e.g., a tin-silver plating layer) may be formed over bond pad 104 to facilitate an enhanced electrical connection with the micro-bump (e.g., solder).

In either of these arrangements, redistribution structures in redistribution layer 96 may be formed using wafer-level processes. While metal layers on redistribution layer 96 are described to implement inter-die connection structures, some portions of the metal layers on redistribution layer 96 may also implement external package connections (e.g., external connections 84-3 in FIG. 3 having bond pad and/or metal layers formed in redistribution layer 96).

Once the suitable inter-die connection structures (e.g., hybrid bond connection structures, micro-bump connection structures, etc.) are formed on the top side (in the perspective of FIG. 4E) of each die 50, a corresponding die 60 may be mounted to the top side of each die 50 in the stacked-wafer structure.

Unlike the processes described in connection with FIGS. 4A-4D, the mounting of die 60 to die 50 in the stacked-wafer structure may be a die-to-wafer process. In particular, a wafer of dies 60 (each having corresponding inter-die connection structures 64 and a thinned substrate 62) may first be singulated (e.g., cut into a plurality of individual dies 60) before being mounted to the stacked-wafer structure containing dies 40 and 50.

As shown in FIG. 4E, a pick-and-place system such as system 106 may pick up one or more singulated dies 60 at a time and place the singulated dies 60 onto corresponding locations on the stacked-wafer structure with wafer 41 (containing dies 40) mounted to wafer 51 (containing dies 50). In the example of FIG. 4E, two illustrative singulated dies 60 are shown to be placed at (or about to be placed at) their corresponding locations on the top side (in the perspective of FIG. 4E) of wafer 51. Alignment tools and/or markings may help align inter-die connection structures 64 on the bottom side (e.g., the side with interconnect layer 65) of each singulated die 60 to corresponding inter-die connection structures on the top side of wafer 51 (e.g., inter-die connection structures 84-2).

After each die 60 has been placed, a bonding process (e.g., a hybrid bonding process, a reflow process, etc.) may be performed to physically and electrically connect each die 60 to a corresponding (un-singulated) die 50 stacked on top of a corresponding (un-singulated) die 40. After singulated dies 60 have been bonded to the top surface (in the perspective of FIG. 4E) of stacked-wafer structure containing wafers 41 and 51, the stacked-wafer structure may be partially cut between adjacent stacked-die structures (e.g., along dashed line 110 as shown in FIG. 4E). The partial cut may extend from the top surface of the stacked-wafer structure and into layer 46, but stop within layer 46 as indicated by line 112.

As shown in FIG. 4F, a molding compound such as molding compound 68 may be disposed over the top surface (in the perspective of FIG. 4F) of the stacked-wafer structure and mounted dies 60. Molding compound 68 may also extend into the partial cut into the stacked-wafer structure described in connection with FIG. 4E. As such, molding compound 58 may extend along the peripheral sides or lateral edges of each stacked-die structure to line 112 in layer 46.

To form the external electrical connections to each stacked-die package, one or more wafer level processes may be used to form openings 118 in molding compound 68 aligned with external connection structures 84-3 on each die 50. Solder bumps 66 may then be deposited in openings 118, thereby enabling soldering connection to each stacked-die package. The encapsulated stacked-wafer structure having externally exposed solder connections may then be singulated or diced (e.g., along line 120 that extends entirely through the stacked-wafer structure) to form a plurality of stacked-die packages 34 (FIG. 3).

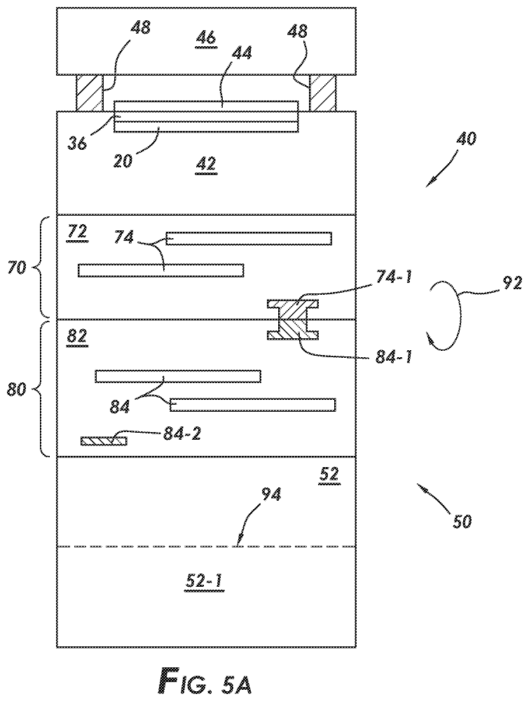

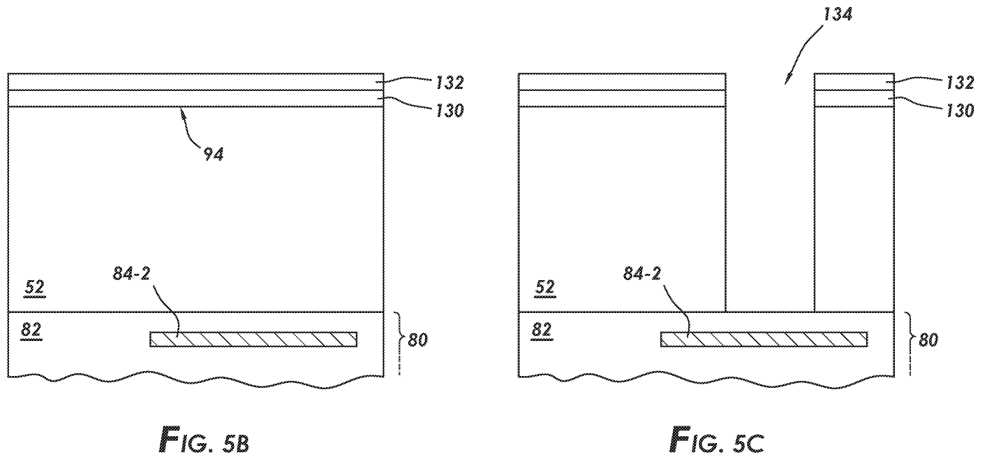

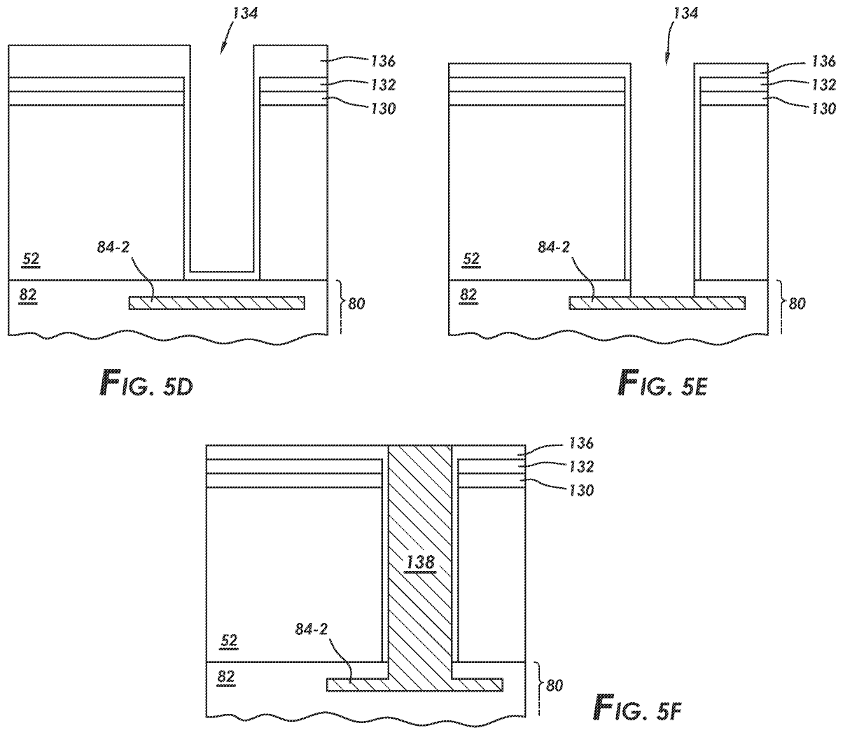

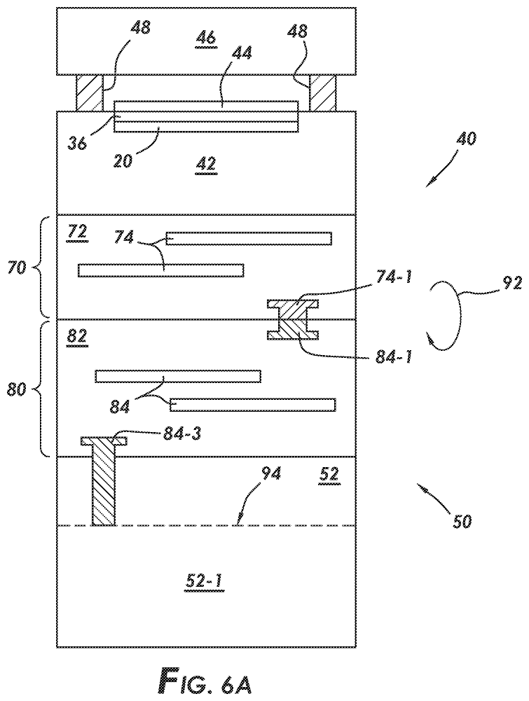

In some illustrative arrangements, each die 50 (e.g., the un-singulated wafer containing dies 40) when bonded to a corresponding die 40 (e.g., the un-singulated wafer containing dies 40) may include inter-die connection structures 84-2 (for connecting to die 60) that excludes through-silicon via portions extending into substrate 52. Such a partially formed stacked-wafer structure is shown in FIG. 5A, which is analogous to the partially formed stacked-wafer structure in FIG. 4C containing the through-silicon via portion of connection structure 84-2. In other words, the same processes as described in connection with FIGS. 4A-4C may be used to arrive at the partially formed stacked-wafer structure shown in FIG. 5A (except the starting wafer of dies 50 may lack the aforementioned through-silicon via portions in substrate 52).

Accordingly, in the arrangement shown in FIG. 5A, prior to forming redistribution layer structures as described in connection with FIG. 4D, through-silicon vias for connection structures 84-2 may first need to be formed. FIGS. 5B-5F illustrate one or more processes that may be employed to form illustrative through-silicon vias for connection structures 84-2.

FIGS. 5B-5F illustrate wafer-level processes by showing a single illustrative inter-die connection structure in order not to obscure the present embodiments. As an example, while FIGS. 5B-5F show processing for forming a single inter-die connection structure, these processes may, if desired, take place (simultaneously) across multiple inter-die connection structures 84-2 on a single die 50 (stacked on a corresponding die 40), and/or take place (simultaneously) across multiple inter-die connection structures 84-2 on a wafer of dies 50 (stacked on a corresponding wafer containing dies 40).

To prepare for the formation of through-substrate vias, processing of the bottom side (in the perspective of FIG. 5A) of each die 50 may be performed. If desired, the stacked-wafer structure may be flipped as indicated by arrow 92 to facilitate processing of the bottom side of each die 50. In particular, in preparation for forming through-silicon via portions of inter-die connection structures 84-2 on the bottom side of each die 50, substrate 52 may be thinned (at the wafer-level) to a desired thickness. In particular, the thinning process may remove substrate portion 52-1 and result in a new surface 94. The new surface 94 may be near or at a desired end of a through-silicon via portion of the inter-die connection structure 84-2 in substrate 52.

Thereafter, as shown in FIG. 5B, passivation layers such as silicon nitride layer 130 and silicon dioxide layer 132 may be formed (e.g., sequentially deposited) on new surface 94 of substrate 52. As shown in FIG. 5C, an opening such as opening 134 aligning to inter-die connection structure 84-2 (e.g., aligned to the metal layer in interconnect layer 80 forming a portion of structure 84-2) may be formed using a patterning and silicon (substrate) etch process that stops at dielectric layer 82.

As shown in FIG. 5D, an additional silicon dioxide liner layer may be deposited over the top surface (in the perspective of FIG. 5D) of substate 52. As shown in FIG. 5E, an additional blanket etch step may further extend opening 134 to the metal layer in interconnection layer 80 that forms a portion of inter-die connection structure 84-2. As shown in FIG. 5F, opening 134 may subsequently be filled with a conductive material (e.g., copper) using a seed layer and electrochemical deposition (as an example). A planarization process (e.g., chemical-mechanical polish (CMP) process) may be used to planarize the top surface (in the perspective of FIG. 5D) of oxide layer 136 and through-silicon via 138.

Performing the processes described in connection with FIGS. 5B-5F on the partially formed stacked-wafer structure shown in FIG. 5A may result in the partially formed stacked-wafer structure in FIG. 4C. As such, processing may proceed via the processes described in connection with FIGS. 4D-4F to form stacked-integrated circuit packages 34 (FIG. 3). In other words, stacked-die packages 34 may be formed whether or not wafer 51 (containing dies 50) are initially provided with through-silicon vias structures for connecting to dies 60. The timing for the formation of the through-silicon via structures may be adjusted as desired.

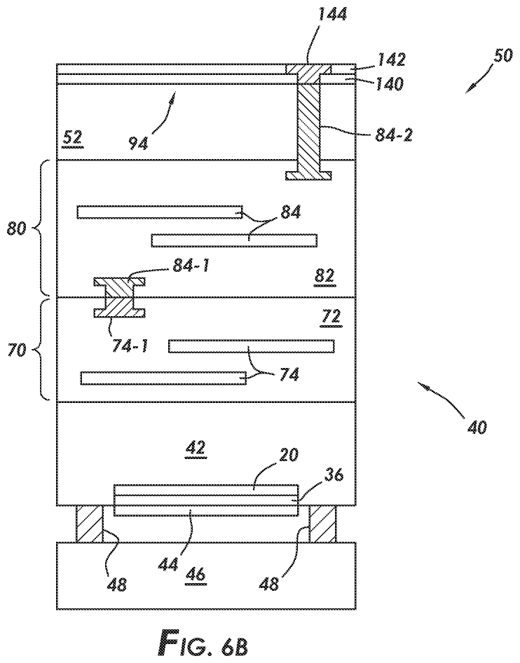

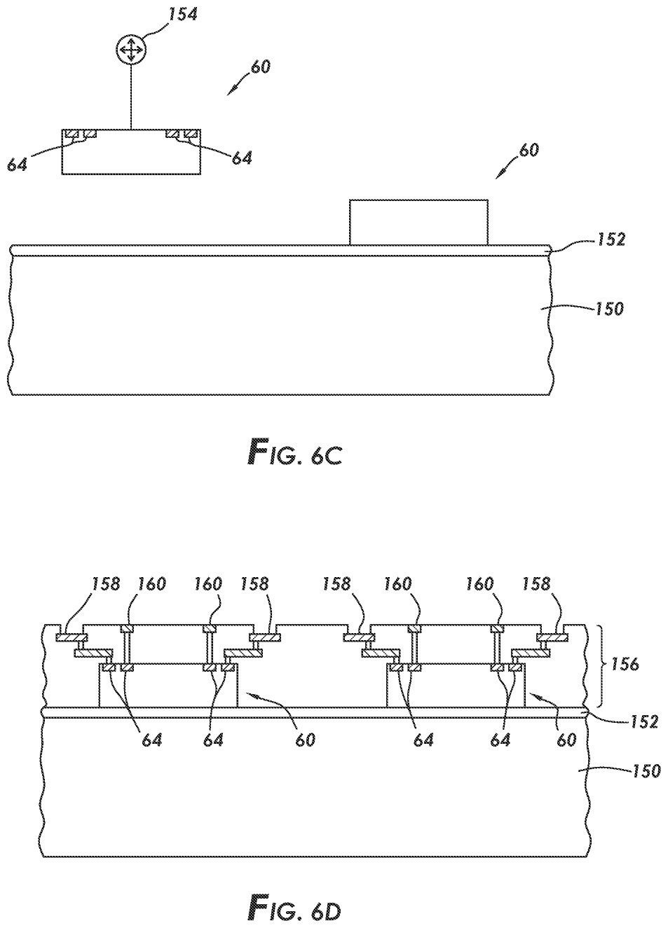

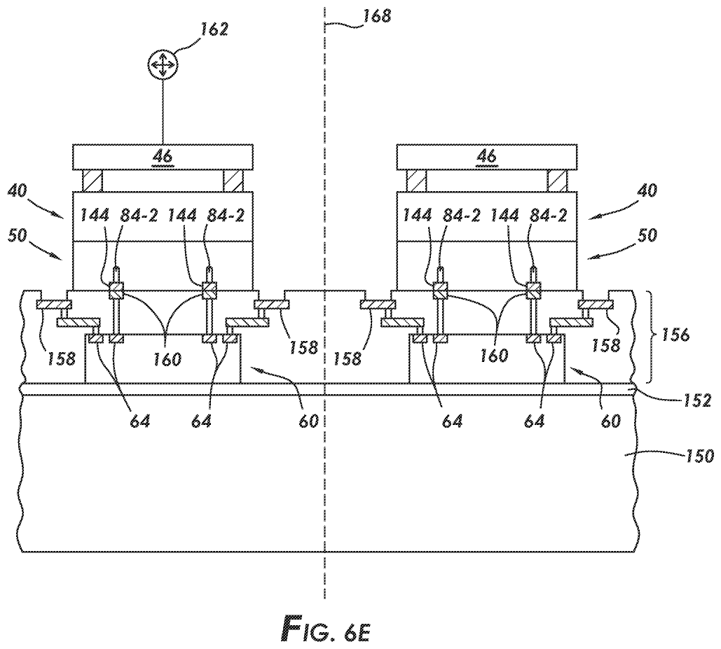

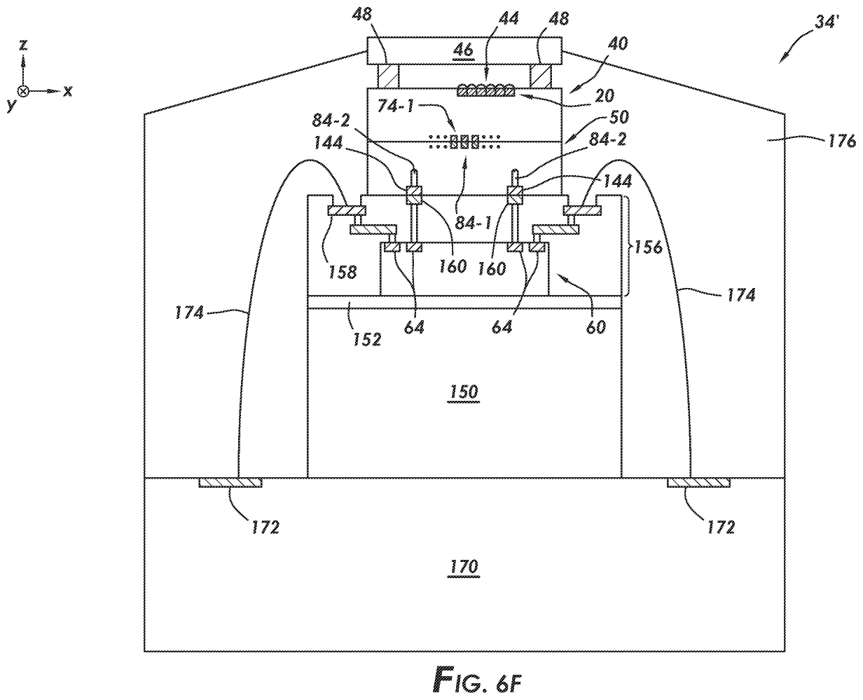

While in the illustrative examples described in connection with FIGS. 3, 4A-4F, and 5A-5F, solder balls (e.g., solder balls 66) are used for provide package connections (e.g., to a printed circuit board), this is merely illustrative. If desired, stacked-die packages may be configured with other types of package connection structures such as wire-bond connections. FIGS. 6A-6F illustrate one or more processes that may be employed to form illustrative stacked-die packages with wire-bond package connections.

In particular, FIGS. 6A and 6B illustrate wafer-level processes at a die-level (e.g., by showing individual dies) in order not to obscure the present embodiments. As an example, while FIGS. 6A and 6B show processing of first die 40, second die 50, and the stacked-die structure with dies 40 and 50 stacked on one another, these processes may, if desired, take place (simultaneously) across a first wafer of integrated circuit dies 40, a second wafer of integrated circuit dies 50, and the stacked-wafer structure resulting from the first and second wafers being stacked on one another.

In particular, processing to form stacked-die packages with wire-bond connections may share some of the same processes as described in connection with FIGS. 4A-4C, thereby arriving at the partially formed stacked-wafer structure shown in FIG. 6A (which is the same as FIG. 4C).

After substrate 52 has been thinned to new surface 94 and the stacked-wafer structure has been optionally flipped as indicated by arrow 92, processing may proceed with the processes illustrated in FIG. 6B. As shown in FIG. 6B, passivation layers such as silicon nitride layer 140 and silicon dioxide layer 142 may be formed on new surface 94 of substrate 52, and an exposed bond pad structure 144 connected to the through-silicon via portion of inter-die connection structure 84-2 may be formed in silicon dioxide layer 142. As an example, these structures may be deposited and patterned using a single damascene process.

Unlike the processes in FIGS. 6A and 6B, processes in FIGS. 6C-6E may utilize die-to-wafer processes. In particular, a wafer of dies 60 (each having corresponding external and/or inter-die connection structures 64 and a thinned substrate 62) may first be singulated (e.g., cut into a plurality of individual dies 60) before being mounted to a carrier wafer.

As shown in FIG. 6C, additional processing may begin with dies 60. In particular, a pick-and-place system such as system 154 may pick up one or more singulated dies 60 (at a time) and place the singulated dies 60 onto corresponding locations on a carrier substrate (wafer) such as substrate 150. In the example of FIG. 6C, two illustrative singulated dies 60 are shown to be placed at (or about to be placed at) their corresponding locations on the top side (in the perspective of FIG. 6C) of wafer 150 or more specifically on the top side of an attachment layer 152 (e.g., an adhesive layer) attaching each die 60 to a corresponding location on top of wafer 150. Alignment tools and/or markings may help align inter-die connection structures 64 on the top side of each singulated die 60 to enable inter-die connections to a corresponding die 50 to be mounted on top of die 60.

As shown in FIG. 6D, a redistribution layer such as redistribution layer 156 having one or more conductive layers may be formed over and around each die 60. In particular, metal layers in redistribution layer 156 may form fan-out structures connected to external bond pads 158. Each bond pad 158 may be coupled to a corresponding external connection structure 64 on die 60 via one or more metal layers and/or conductive vias in redistribution layer 156. Additionally, inter-die connection bond pads 160 may also be formed from metal layers in redistribution layer 156. Each bond pad 160 may be coupled to a corresponding inter-die connection structure 64 on die 60 via one or more metal layers and/or conductive vias in redistribution layer 156. In such a manner, the top surface of redistribution layer 156 may be provided with connection structures (e.g., bond pads) for both inter-die connections (using bond pads 158) and external package connections (using bond pads 160).

Following the formation of these connections, processing may proceed with one or more die-to-wafer processes. In particular, the stacked-wafer structure containing a wafer with dies 40 mounted to a wafer with dies 50 may be diced to form singulated stacked-die structures (e.g., the stacked-die structure shown in FIG. 6B). As shown in FIG. 6E, a pick-and-place system such as system 162 may pick up one or more singulated stacked-die structures (e.g., die 40 stacked on die 50 as shown in FIG. 6B) and place the singulated stacked-die structures onto corresponding locations on redistribution layer 156 on carrier wafer 150.

In the example of FIG. 6E, two illustrative singulated stacked-die structures are shown to be placed at their corresponding locations on the top side (in the perspective of FIG. 6E) of redistribution layer 156. Alignment tools and/or markings may help align inter-die connection structures 84-2 on each die 50 (e.g., bond pad structures 144 of connection structure 84-2 on the exposed bottom surface of each die 50) to corresponding inter-die connection structures on the top side of redistribution layer 156 (e.g., bond pad structures 160 connected to inter-die connection structures 64 on a corresponding die 60).

After each of the stacked-die structures has been placed, a bonding process (e.g., a hybrid bonding process, a reflow process, etc.) may be performed to physically and electrically connect each singulated stacked-die structure (containing dies 40 and 50) through redistribution layer 156 to a corresponding (singulated) die 60 stacked on top of carrier wafer 150. After the singulated stacked-die structures have been bonded to the top surface of redistribution layer 156, the resulting stacked-die structure may be singulated (e.g., diced) between each pair of adjacent stacked-die structures (e.g., along dashed line 168 as shown in FIG. 6E).

Each singulated stacked-die structure may be wire-bonded to another substrate and encapsulated to form a stacked-die package. In particular, as shown in FIG. 6F, the singulated stacked-die structure with glass layer 46, die 40, die 50, redistribution layer 156, die 60, and (permanent) carrier substrate 150 may be mounted onto a wire-bond substrate such as substrate 170 having bond pads 172. External connection bond pads 158 on the stacked-die structure may be wire-bonded to corresponding bond pads 172 on substrate 170 using bond-wires 174. If desired, other functional circuitry (external to package 34′) on substrate 170 may be connected to the stacked-die structure through substrate 170 and bond pads 172. If desired, substrate 170 may further be mounted to and connected to a printed circuit board, and external connections from the stacked-die package to the printed circuit board may use bond-wires 174.

An encapsulant such as encapsulant 176 may be used to encapsulate the stacked-die structure and bond-wires 174. In particular, encapsulant 176 may extend from the peripheral sides of glass layer 46 to the top surface (in the perspective of FIG. 6F) of substrate 170, thereby allowing light to be received at pixel array 20 through the top surface (in the perspective of FIG. 6F) of glass layer 46, while protecting the encapsulated structures of stacked-die package 34′.

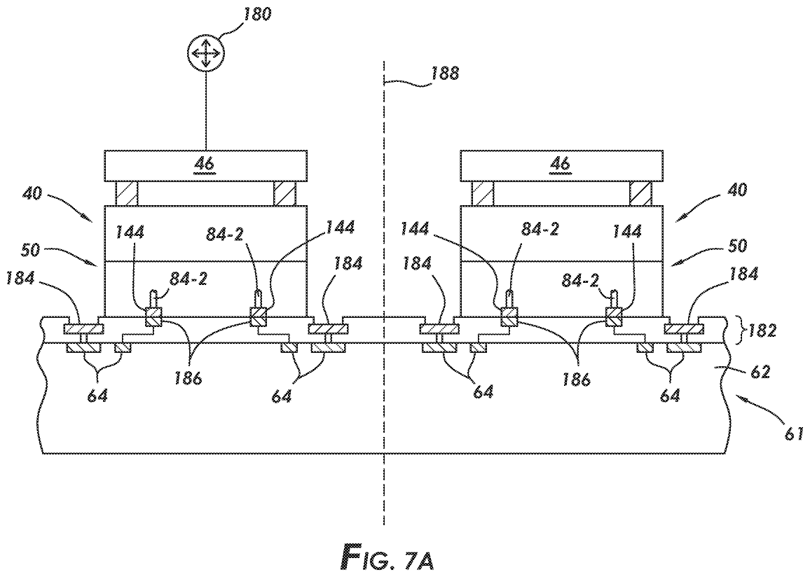

While in the illustrative examples described in connection with FIGS. 3, 4A-4F, 5A-5F, and 6A-6F, die 60 may be smaller than (e.g., have a length between opposing lateral edges smaller than) dies 40 and 50 (e.g., the stacked-die structure with die 40 mounted to die 50), this is merely illustrative. If desired, the stacked-die structure containing dies 40 and 50 may be mounted to a base (bottom) die 60 with a larger footprint than (e.g., have a length between opposing lateral edges greater than) one or both of dies 40 and 50. FIGS. 7A-7B illustrate one or more processes that may be employed to form illustrative stacked-die packages with a larger base die 60 (e.g., larger footprint, outline, lateral dimension, etc.) than the stacked-die structure containing dies 40 and 50.

In the scenario where a larger base die 60 (e.g., a bottom die to which one or more dies are mounted) is used, singulating a wafer of dies 60 and placing the singulated dies 60 on a carrier wafer (as shown in FIG. 6C) may be unnecessary. As shown in FIG. 7A, wafer 61 containing un-singulated dies 60 may be left intact, and a redistribution layer such as redistribution layer 182 may be formed directly on the top surface (in the perspective of FIG. 7A) of wafer 61. Metal layers in redistribution layer 182 may be used to form external and inter-die connection structures connecting to connection structures 64 on die 60 of wafer 61.

In particular, bond pads 184 configured to provide (wire-bond) external connections may be formed at the top surface (in the perspective of FIG. 7A) of redistribution layer 182 and may be connected to corresponding external connection structures 64 on dies 60. Additionally, bond pads 186 configured to provide inter-die connections may be formed at the top surface of redistribution layer 182 and may be connected to corresponding inter-die connection structures 64 on dies 60. Bond pads 184 and 186 may be coupled to corresponding connection structure 64 via one or more metal layers and/or vias in redistribution layer 182, if desired. Because each die 60 is larger than (e.g., has a larger lateral outline than) the corresponding die 50, metal layers in redistribution layer 182 may form fan-in structures toward die 50 (e.g., fan-out structures toward wafer 61 or dies 60). Structures in redistribution layer 182 may be formed as part of wafer-level processes.

After forming redistribution layer 182 (e.g., bond pads 184 and 186, and other metal layers), a pick-and-place system such as system 180 may pick up one or more singulated stacked-die structures (e.g., die 40 stacked on die 50 as shown in FIG. 6B) and place the singulated stacked-die structures onto corresponding locations on redistribution layer 182 on wafer 61. In the example of FIG. 7A, two illustrative singulated stacked-die structures are shown to be placed at their corresponding locations on the top side (in the perspective of FIG. 7A) of redistribution layer 182. Alignment tools and/or markings may help align inter-die connection structures 84-2 on each die 50 (e.g., bond pad structures 144 of connection structures 84-2 on the exposed bottom surface of each die 50) to corresponding inter-die connection structures on the top side of redistribution layer 182 (e.g., bond pad structure 186 connected to inter-die connection structures 64 on a corresponding die 60).

After each of the stacked-die structures has been placed, a bonding process (e.g., a hybrid bonding process, a reflow process, etc.) may be performed to physically and electrically connect each singulated stacked-die structure (containing dies 40 and 50) through redistribution layer 182 to a corresponding (un-singulated) die 60 on wafer 61. After the singulated stacked-die structures have been bonded to the top surface of redistribution layer 182, the resulting stacked-die structures may be singulated (e.g., diced) between each pair of adjacent stacked-die structures (e.g., along dashed line 188 as shown in FIG. 7A).

Each singulated stacked-die structure may be wire-bonded to another substrate and encapsulated to form a stacked-die package. In particular, as shown in FIG. 7B, the singulated stacked-die structure with glass layer 46, die 40, die 50, and redistribution layer 182, and die 60 may be mounted onto a wire-bond substrate such as substrate 190 having bond pads 192. External connection bond pads 184 on the stacked-die structure may be wire-bonded to corresponding bond pads 192 on substrate 190 using bond-wires 194. If desired, other functional circuitry (external to package 34″) on substrate 190 may be connected to the stacked-die structure through substrate 190 and bond pads 192. If desired, substrate 190 may further be mounted to and connected to a printed circuit board, and external connections from the stacked-die package to the printed circuit board may use bond-wires 194.

An encapsulant such as encapsulant 196 may be used to encapsulate the stacked-die structure and bond-wires 194. In particular, encapsulant 196 may extend from the peripheral sides of glass layer 46 to the top surface (in the perspective of FIG. 7B) of substrate 190, thereby allowing light to be received at pixel array 20 through the top surface (in the perspective of FIG. 7B) of glass layer 46, while protecting the encapsulated structures of stacked-die package 34″.

The processes described in connection with FIGS. 4A-4F, 5A-5F, 6A-6F, 7A, and 7B may utilize a process that attaches a glass or protective layer 46 to wafer 41 containing un-singulated dies 40. If desired, as an alternative, a temporary carrier substrate (wafer) may be attached instead of layer 46 to wafer 41, and layer 46 may be attached at a subsequent step (after the temporary carrier substrate has been removed).

The processes described in connection with FIGS. 4A-4F, 5A-5F, 6A-6F, 7A, and 7B may utilize a process that picks and places dies and/or stacked-die structures onto a wafer and/or a stacked-wafer structure for a die-to-wafer level bonding process. If desired, as an alternative, a pick-and-place system may instead pick and place the dies and/or stack-die structure onto a temporary carrier substrate (wafer). Thereafter, a wafer-to-wafer process may be used to attach the wafer or stacked-wafer structure onto the dies and/or stacked-die structure mounted to the temporary carrier substrate. The temporary carrier substate may subsequently be removed.

In one illustrative alternative arrangement in connection with FIG. 4C, a first temporary carrier substrate may be mounted to the top side (in the perspective of FIG. 4C) of dies 40 on an un-singulated wafer instead of glass layer 46. In one illustrative alternative arrangement in connection with FIG. 4E, individual dies 60 may be picked and placed onto a second temporary carrier substrate instead of being directly mounted to the top side (in the perspective of FIG. 4E) of the stacked-wafer structure containing dies 40 and 50. The stacked-wafer structure containing dies 40 and 50 may then be mounted to dies 60 on top of the second temporary carrier substrate and bonded with dies 60. Subsequently, the first temporary carrier substrate may be removed and replaced with (glass) layer 46, and the second temporary carrier substrate may be removed. The remaining processes as described in connection with FIGS. 4A-4F may remain the same. If desired, analogous alternatives may be used in connection with the processes described in connection with FIGS. 5A-5F, 6A-6F, and/or 7A and 7B.

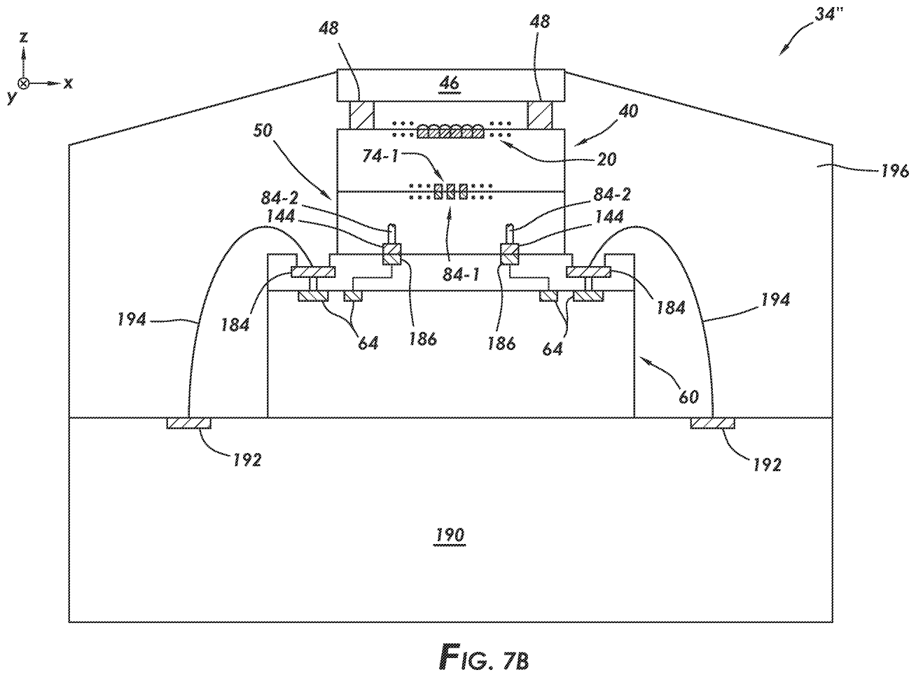

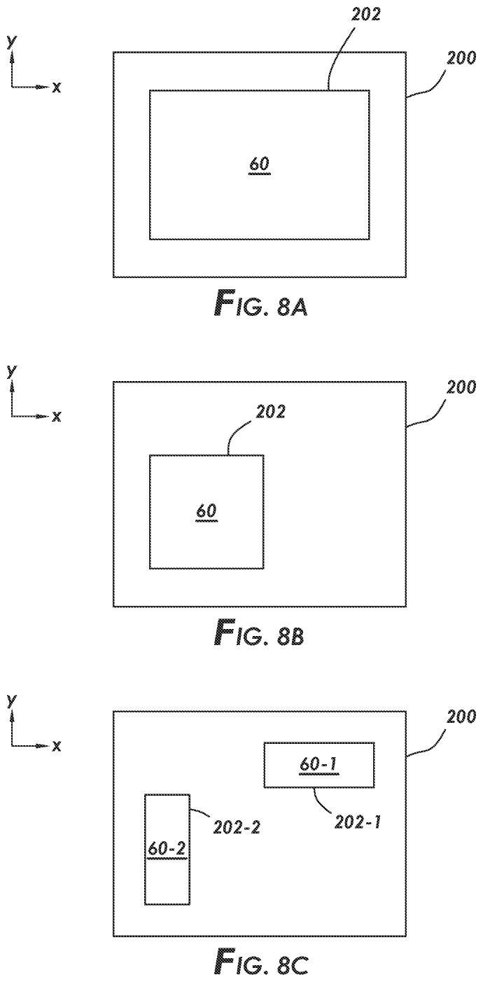

While, in the illustrative examples described in connection with FIGS. 3, 4A-4F, 5A-5F, 6A-6F, 7A, and 7B, a single base die 60 may be placed at a central location with respect to stacked dies 40 and 50, this is merely illustrative. If desired, the base die(s) may have any suitable placement when mounted to die 50 (already mounted to die 40). FIGS. 8A-8B show illustratively outlines of stacked dies that may be implemented in a stacked-die package (e.g., in package 34 of FIG. 3, in package 34′ of FIG. 6F, in package 34″ of FIG. 7B, etc.).

In the example of FIG. 8A, a top stacked-die structure (e.g., die 40 mounted to die 50) may have a lateral outline 200 (e.g., in the x-y plane with respect to the x-y-z axes shown in FIG. 3, FIG. 6F, or FIG. 7B), while a bottom or base die 60 has a lateral outline 202. In the illustrative arrangement of FIG. 8A, die 60 having outline 202 may be mounted in the stacked-die package such that it is centered with respect to outline 200 of die 40 and/or die 50 (e.g., of the stacked-die structure).

In the example of FIG. 8B, a top stacked-die structure (e.g., die 40 mounted to die 50) may have the same lateral outline 200, while a bottom or base die 60 has a lateral outline 202. In the illustrative arrangement of FIG. 8B, die 60 having outline 202 may be mounted in the stacked-die package such that it is off-center from a center of outline 200 of die 40 and/or die 50 (e.g., of the stacked-die structure).

In the example of FIG. 8C, a top stacked-die structure (e.g., die 40 mounted to die 50) may have the same lateral outline 200. Two separate integrated circuit dies (e.g., one implementing at least pixel row control circuitry, one implementing at least pixel column readout circuitry, one implementing signal processing circuitry, one implementing memory circuitry, etc.) may be separately mounted to the stacked-die structure (instead of mounting a single die 60). If desired, first die 60-1 having outline 202-1 and/or second die 60-2 having outline 202-2 may both be mounted in the stacked-die package such that they are each off-center from a center of outline 200 of die 40 and/or die 50 (e.g., of the stacked-die structure). In one illustrative arrangement, die 60-1 may be mounted such that it is elongated along a first dimension (e.g., along the x-axis) to better facilitate the formation of inter-die pixel column connections, while die 60-2 may be mounted such that it is elongated along a second dimension (e.g., along the y-axis) to better facilitate the of inter-die pixel row connections (as an example).

Various embodiments have been described illustrating stacked-die integrated circuit packages.

As an example, an image sensor package (e.g., a stacked-die package) may include a first integrated circuit die having image sensor pixel circuitry, a second integrated circuit die having charge storage circuitry and mounted to the first integrated circuit die, and a third integrated circuit die having pixel readout circuitry and mounted to the second integrated circuit die. The third integrated circuit die may have a lateral outline (e.g., at least one lateral dimension between opposing lateral edges) different from a lateral outline of the second integrated circuit die.

In particular, the third die may include an inter-die connection structure connected to the second die and disposed on a side of the third die facing the second die. The second die may have an interconnect layer forming an inter-die connection structure that connects to the inter-die connection structure of the third die. The interconnect layer of the second die may be formed on a side of the second die facing the first die. The first die may have an interconnect layer forming an inter-die connection structure that connects to the second die. The interconnect layer of the first die may be formed on a side of the first die facing the second die. The interconnect layer of the second die may form an additional inter-die connection structure that connects to the inter-die connection structure of the first die. If desired, the inter-die connection structure of the first die and the additional inter-die connection structure of the second die may form a hybrid bond.

In some arrangements, a metal structure (e.g., a portion of a metal layer) in a redistribution layer at an additional side of the second die opposite the side of the second die may form a portion of the inter-die connection structure of the second die that connects to the inter-die connection structure of the third die. If desired, the inter-die connection structure of the second die and the inter-die connection structure of the third die may form a hybrid bond. If desired, the inter-die connection structure of the second die and the inter-die connection structure of the third die may form a micro-bump connection.

In some arrangements, the metal structure in the redistribution layer may form a fan-in structure toward the third integrated circuit die, while in other arrangements, the metal structure in the redistribution layer may form a fan-out structure toward the third integrated circuit die.

The image sensor pixel circuitry in the first die may include image sensor pixels arranged in a plurality of lines (e.g., a plurality of pixel columns, a plurality of pixel rows, etc.). Each image sensor pixel on the first die may be connected to the second die via a corresponding an inter-die connection between the first and second dies (e.g., at least one inter-die connection between the first and second dies exists for each of the image sensor pixel). Each line in the plurality of lines may be coupled to a corresponding inter-die connection between the second and third dies (e.g., at least one inter-die connection between the second and third dies exists for each line of image sensor pixels).

In scenarios where the inter-die connections between the second and third dies are coupled to pixel column readout circuitry on the third die, the plurality of lines may be a plurality of pixel columns. In scenarios where the inter-die connections between the second and third dies are coupled to pixel row control circuitry on the third die, the plurality of lines may be a plurality of pixel rows.

More generally, and as another example, an integrated circuit package (e.g., implementing other imaging or non-imaging circuitry) may include the first, second, and third dies as configured above (e.g., stacked on top of one another as described herein). The third die may have a lateral dimension (e.g., between opposing lateral edges) that is less than or greater than a lateral dimension of the second die and/or the first die.

If desired, a redistribution metal layer between the second and third dies may form external connection structures (e.g., bond pads) configured to form wire-bond connections.

In accordance with an embodiment, an image sensor may include: a first integrated circuit die having image sensor pixel circuitry; a second integrated circuit die having charge storage circuitry, the second integrated circuit die being mounted to the first integrated circuit die; and a third integrated circuit die having pixel readout circuitry and having an inter-die connection structure connected to the second integrated circuit die and disposed on a side of the third integrated circuit die facing the second integrated circuit die. The third integrated circuit die may have a lateral outline different from a lateral outline of the second integrated circuit die.

In accordance with another embodiment, the second integrated circuit die may have an interconnect layer forming an inter-die connection structure that connects to the inter-die connection structure of the third integrated circuit die. The interconnect layer may be formed on a side of the second integrated circuit die facing the first integrated circuit die.

In accordance with another embodiment, the first integrated circuit die may have an interconnect layer forming an inter-die connection structure that connects to the second integrated circuit die. The interconnect layer of the first integrated circuit die may be formed on a side of the first integrated circuit die facing the second integrated circuit die.

In accordance with another embodiment, the interconnect layer of the second integrated circuit die may form an additional inter-die connection structure that connects to the inter-die connection structure of the first integrated circuit die.

In accordance with another embodiment, the inter-die connection structure of the first integrated circuit die and the additional inter-die connection structure of the second integrated circuit die may form a hybrid bond.

In accordance with another embodiment, a metal structure in a redistribution layer at an additional side of the second integrated circuit die opposite the side of the second integrated circuit die may form a portion of the inter-die connection structure of the second integrated circuit die that connects to the inter-die connection structure of the third integrated circuit die.

In accordance with another embodiment, the inter-die connection structure of the second integrated circuit die and the inter-die connection structure of the third integrated circuit die may form a hybrid bond.

In accordance with another embodiment, the inter-die connection structure of the second integrated circuit die and the inter-die connection structure of the third integrated circuit die may form a micro-bump connection.

In accordance with another embodiment, the metal structure in the redistribution layer may form a fan-in structure toward the third integrated circuit die.

In accordance with another embodiment, the metal structure in the redistribution layer may form a fan-out structure toward the third integrated circuit die.

In accordance with an embodiment, an integrated circuit package may include: a first integrated circuit die; a second integrated circuit die having first and second opposing sides and attached to the first integrated circuit die at the first side; and a third integrated circuit die having inter-die connection structures at a side facing the second integrated circuit die and attached to the second integrated circuit die at the side of the third integrated circuit die. The third integrated circuit die may have a dimension between opposing lateral edges of the third integrated circuit die that is different than a dimension between corresponding opposing lateral edges of the second integrated circuit die.

In accordance with another embodiment, the dimension between the opposing lateral edges of the third integrated circuit die may be less than the dimension between the corresponding opposing lateral edges of the second integrated circuit die.

In accordance with another embodiment, the second integrated circuit die may include a metal layer at the first side and a conductive via that extends through a substrate of the second integrated circuit die. The metal layer and the conductive via may form an inter-die connection structure that connects to a given one of the inter-die connection structures of the third integrated circuit die.

In accordance with another embodiment, the second integrated circuit die may include an additional metal layer at the second side that form at least a part of the inter-die connection structure connecting to the given one of the inter-die connection structures of the third integrated circuit die.

In accordance with another embodiment, a redistribution metal layer on the side of the third integrated circuit die may have external connection structures configured to form wire-bond connections.

In accordance with another embodiment, the dimension between the opposing lateral edges of the third integrated circuit die may be greater than the dimension between the corresponding opposing lateral edges of the second integrated circuit die. A redistribution metal layer on the side of the third integrated circuit die may have external connection structures configured to form wire-bond connections.

In accordance with an embodiment, an image sensor package may include: a first integrated circuit die having image sensor pixels arranged in a plurality of lines; a second integrated circuit die mounted to the first integrated circuit die and having an inter-die connection to the first integrated circuit die for each of the image sensor pixels; and a third integrated circuit die mounted to the second integrated circuit die and having an inter-die connection to the second integrated circuit die for each line in the plurality of lines, each inter-die connection being on a side of the third integrated circuit die facing the second integrated circuit die.

In accordance with another embodiment, the third integrated circuit die may have a lateral outline different from a lateral outline of the second integrated circuit die.

In accordance with another embodiment, the plurality of lines may be a plurality of pixel columns. The third integrated circuit die may include pixel column readout circuitry.

In accordance with another embodiment, the plurality of lines may be a plurality of pixel rows. The third integrated circuit die may include pixel row control circuitry.

The foregoing embodiments may be implemented individually or in any combination. It will be recognized by one of ordinary skill in the art, that the present exemplary embodiments may be practiced without some or all of the corresponding specific details. In some instances, well-known operations have not been described in detail in order not to unnecessarily obscure the embodiments described herein. The foregoing is merely illustrative of the principles of this invention and various modifications can be made by those skilled in the art without departing from the scope and spirit of the invention.

1. An image sensor comprising:
a first integrated circuit die having image sensor pixel circuitry;
a second integrated circuit die having charge storage circuitry, the second integrated circuit die being mounted to the first integrated circuit die; and
a third integrated circuit die having pixel readout circuitry and having an inter-die connection structure connected to the second integrated circuit die and disposed on a side of the third integrated circuit die facing the second integrated circuit die, the third integrated circuit die having a lateral outline different from a lateral outline of the second integrated circuit die.

2. The image sensor defined in claim 1, wherein the second integrated circuit die has an interconnect layer forming an inter-die connection structure that connects to the inter-die connection structure of the third integrated circuit die, the interconnect layer being formed on a side of the second integrated circuit die facing the first integrated circuit die.

3. The image sensor defined in claim 2, wherein the first integrated circuit die has an interconnect layer forming an inter-die connection structure that connects to the second integrated circuit die, the interconnect layer of the first integrated circuit die being formed on a side of the first integrated circuit die facing the second integrated circuit die.

4. The image sensor defined in claim 3, wherein the interconnect layer of the second integrated circuit die forms an additional inter-die connection structure that connects to the inter-die connection structure of the first integrated circuit die.

5. The image sensor defined in claim 4, wherein the inter-die connection structure of the first integrated circuit die and the additional inter-die connection structure of the second integrated circuit die form a hybrid bond.

6. The image sensor defined in claim 2, wherein a metal structure in a redistribution layer at an additional side of the second integrated circuit die opposite the side of the second integrated circuit die forms a portion of the inter-die connection structure of the second integrated circuit die that connects to the inter-die connection structure of the third integrated circuit die.

7. The image sensor defined in claim 6, wherein the inter-die connection structure of the second integrated circuit die and the inter-die connection structure of the third integrated circuit die form a hybrid bond.

8. The image sensor defined in claim 6, wherein the inter-die connection structure of the second integrated circuit die and the inter-die connection structure of the third integrated circuit die form a micro-bump connection.

9. The image sensor defined in claim 6, wherein the metal structure in the redistribution layer forms a fan-in structure toward the third integrated circuit die.

10. The image sensor defined in claim 6, wherein the metal structure in the redistribution layer forms a fan-out structure toward the third integrated circuit die.

11. An integrated circuit package comprising:
a first integrated circuit die;
a second integrated circuit die having first and second opposing sides and attached to the first integrated circuit die at the first side; and
a third integrated circuit die having inter-die connection structures at a side facing the second integrated circuit die and attached to the second integrated circuit die at the side of the third integrated circuit die, wherein the third integrated circuit die has a dimension between opposing lateral edges of the third integrated circuit die that is different than a dimension between corresponding opposing lateral edges of the second integrated circuit die.

12. The integrated circuit package defined in claim 11, wherein the dimension between the opposing lateral edges of the third integrated circuit die is less than the dimension between the corresponding opposing lateral edges of the second integrated circuit die.

13. The integrated circuit package defined in claim 12, wherein the second integrated circuit die includes a metal layer at the first side and a conductive via that extends through a substrate of the second integrated circuit die, and wherein the metal layer and the conductive via form an inter-die connection structure that connects to a given one of the inter-die connection structures of the third integrated circuit die.

14. The integrated circuit package defined in claim 13, wherein the second integrated circuit die includes an additional metal layer at the second side that form at least a part of the inter-die connection structure connecting to the given one of the inter-die connection structures of the third integrated circuit die.

15. The integrated circuit package defined in claim 12, wherein a redistribution metal layer on the side of the third integrated circuit die has external connection structures configured to form wire-bond connections.

16. The integrated circuit package defined in claim 11, wherein the dimension between the opposing lateral edges of the third integrated circuit die is greater than the dimension between the corresponding opposing lateral edges of the second integrated circuit die, and wherein a redistribution metal layer on the side of the third integrated circuit die has external connection structures configured to form wire-bond connections.

17. An image sensor package comprising:
a first integrated circuit die having image sensor pixels arranged in a plurality of lines;
a second integrated circuit die mounted to the first integrated circuit die and having an inter-die connection to the first integrated circuit die for each of the image sensor pixels; and
a third integrated circuit die mounted to the second integrated circuit die and having an inter-die connection to the second integrated circuit die for each line in the plurality of lines, each inter-die connection being on a side of the third integrated circuit die facing the second integrated circuit die.

18. The image sensor package defined in claim 17, wherein the third integrated circuit die has a lateral outline different from a lateral outline of the second integrated circuit die.

19. The image sensor package defined in claim 18, wherein the plurality of lines is a plurality of pixel columns, and wherein the third integrated circuit die comprises pixel column readout circuitry.

20. The image sensor package defined in claim 18, wherein the plurality of lines is a plurality of pixel rows, and wherein the third integrated circuit die comprises pixel row control circuitry.
